(19) United States
(12) Patent Application Publication
(10) Pub. No.: US 2020/0185557 A1
(43) Pub. Date: Jun. 11, 2020

(54) DEVICE FOR HARVESTING SUNLIGHT

(71) Applicant: MORGAN SOLAR INC., Toronto (CA)

(72) Inventors: John Paul MORGAN, Toronto (CA); Stephen CAELERS, Toronto (CA); Brett BARNES, Toronto (CA)

(21) Appl. No.: 16/613,309

(22) PCT Filed: Aug. 3, 2017
(86) PCT No.: PCT/IB2017/054775

§ 371 Date: Nov. 13, 2019

Related U.S. Application Data
(60) Provisional application No. 62/506,734, filed on May 16, 2017.

(51) Int. Cl. H01L 31/0525; H01L 31/054; H01L 31/048; H01L 31/0687; H01L 31/0304

(52) U.S. Cl. CPC H01L 31/0525; H01L 31/0547; H01L 31/0304; H01L 31/06875; H01L 31/0488

(57) ABSTRACT

A device for harvesting sunlight includes a frame and a plurality of sunlight harvesting units. Each sunlight harvesting unit includes a first reflector having a first reflective surface; a second reflector having a second reflective surface; a first light collection unit positioned proximate the second reflector and oriented to receive reflected light from first reflective surface, and a second light collection unit positioned proximate the first reflector and oriented to receive reflected light from the second reflective surface. Each light collection unit has a lower-efficiency photovoltaic cell and a higher-efficiency photovoltaic cell, the cells in thermal communication. The cells are arranged such that sunlight parallel to an axial plane impinging on the reflective surface and reflected thereby is focused on the higher-efficiency photovoltaic cell, and sunlight non-parallel to the axial plane impinging on the reflective surface and reflected thereby is collected by the lower-efficiency photovoltaic cell.

### CROSS-REFERENCE TO RELATED APPLICATIONS

The present application claims priority to U.S. Provisional Patent Application 62/506,734, filed May 16, 2017, entitled “20×”. The entirety of that Provisional Patent Application is incorporated by reference.

### TECHNICAL FIELD

The present technology relates to devices for harvesting sunlight.

### BACKGROUND

In the field of harvesting sunlight and generating solar energy therefrom, conventional photovoltaic panels (sometimes called “solar panels”) are typically used. Conventional photovoltaic panels typically consist of arrays of photovoltaic cells, with each cell consisting of a semiconductor (e.g. monocrystalline silicon, polycrystalline silicon etc.) substrate. The photovoltaic cells collect the solar energy and convert it into an electric current. The power output from such conventional photovoltaic panels is a direct function of the total semiconductor substrate area of the array (that is exposed to sunlight). As a result, in many typical applications, in order to generate a relatively significant electrical output, sizeable arrays of large semiconductor substrates are needed. While such structures are acceptable in many applications (indeed, one finds them in common use throughout the world), they are not ideal for all applications.

In some applications, the efficiency of the photovoltaic cells at converting sunlight into electrical energy is an issue. This efficiency is dependent on the wavelengths of light which are received by the photovoltaic cells. Most data for photovoltaic cell efficiencies describes their efficiency under illumination by sunlight (direct normal irradiance) according to the AM1.5 standard, which corresponds to an air mass 1.5 times the thickness of the atmosphere. (The AM1.5 standard is described in ATSM International document ASTM G173-03(2012), which is incorporated herein by reference in its entirety.) The typical efficiency of the standard silicon photovoltaic cells described above ranges from 15-25% under the AM1.5 spectrum. In some applications, cells of this efficiency range simply do not generate sufficient electrical energy. Higher-efficiency photovoltaic cells, such as those incorporating Gallium compounds in their substrates, do exist, however they tend to be very expensive. They are so expensive in fact, that the use of such materials as direct replacements for standard silicon photovoltaics is currently cost prohibitive in almost all conventional applications.

Partly in response to this situation, concentrating photovoltaic (CPV) systems, such as those described in commonly owned International Patent Application No. PCT/CA2008/000831, published as WO 2008/161561 A1 on Nov. 6, 2008, entitled “Light-Guide Solar Panel and Method of Fabrication Thereof”, were developed. CPV systems employ optics to concentrate light incident thereon (over a relatively large “acceptance area”) down to a smaller photovoltaic cell surface area. Thus, far less of the expensive higher-efficiency semi-conductor substrate material need be used. This can bring down the overall cost of sunlight harvesting systems incorporating such higher-efficiency photovoltaic cells in many applications. Further, by greatly reducing the amount of photovoltaic material needed, still more efficient photovoltaic cells, such as multi-junction cells, can be employed to further increase the power output from these systems.

Concentration, however, does not come without its own disadvantages. Incoming light must generally first interact with some form of concentrating optic, which may attenuate various frequencies and modify the spectrum of light eventually received by a photovoltaic cell. This attenuation and change in spectrum can be quantified by what is known in the art as an “optical transfer function” (OTF) in respect of a particular optical system in question, with respect to particular rays of light and to that particular cell. For the purposes of the present specification, all cell efficiencies described herein take into account the OTFs of the device in which the cell is mounted, unless the contrary is otherwise specified. (A detailed description of optical transfer functions is found in the text Introduction to Fourier Optics, 4^{th} ed., Joseph W. Goodman, W. H. Freeman & Co., May 1, 2017, which is incorporated by reference herein in its entirety.)

Further, by concentrating the same sunlight down to a smaller area (i.e., in comparison with a CPV system with the same sunlight acceptance area as a standard silicon photovoltaic panel, which does not concentrate sunlight), the CPV cells and systems are more susceptible to heating, which can reduce the operating efficiency of the CPV cells, or even damage the CPV cells at some extremes. Thus, typical CPV systems have structures, such as those described in the aforementioned WO '561 publication, or those described in commonly owned International Patent Application No. PCT/US2014/031002, published as WO 2014/146078 A1 on Sep. 18, 2014, entitled “Sunlight Concentrating and Harvesting Device”, for handling thermal energy generated by the CPV cells thereof.

Concentration of sunlight also generally correlates with a CPV sunlight harvesting system having a very narrow sunlight acceptance angle, for example 0.5-2° (degrees). Thus, in such systems there is a very strict requirement that the sunlight acceptance surface of the system be properly aligned with the incoming collimated beam of sunlight. In many cases, little to no power will be generated when the CPV acceptance surface is not almost exactly aligned with the impinging sunlight. Thus, in many applications where CPV systems are employed, the systems are mounted to “trackers”, which are devices that reorient the sunlight acceptance surface during the day so that that surface “tracks” the movement of the sun such that the sunlight continuously (to the extent possible) impinges on the acceptance surface of the system at an angle within the acceptance angle of the system. Some examples of conventional tracking systems are those described in commonly owned International Patent Application No. PCT/IB2012/052723, published as WO 2013/024369 A1 on Feb. 13, 2013 entitled “Self-Ballasted Apparatus for Solar Tracking”.

Design constraints for space-related of solar panel system applications (e.g., systems used to power satellites) differ from those of terrestrial applications. In particular, the mass of the solar panel system is currently a critical design constraint, given the extremely high cost (e.g., on per kilogram basis) to send material into space. Smaller system masses (e.g., on a per generated Watt basis) are highly preferred. The volume of the system is also important as the payload volume of a launch vehicle is limited. Smaller system volumes (e.g., on a per generated Watt basis) are highly preferred. Currently, conventional non-CPV solar panel systems are used in space-related applications. Such systems have tracker mechanisms that are able to reorient the solar panels thereof so that they are able to face the sun as the satellite moves.

Further, conventional non-CPV solar panel systems do not have the aforementioned disadvantage of a narrow acceptance angle; such systems can accept light impinging on the panel over a wide angular range. In current space-related applications this is an important characteristic for a variety of reasons in a number of situations. For example, should a satellite battery be dead (and thus incapable of supplying power to the tracking mechanism to reorient the solar panels to directly face the sun), even when the solar panels indirectly face the sun (i.e., are not at a right angle with respect to a beam of sunlight impinging upon the panel acceptance surface) some amount of electrical energy will be nonetheless be generated. That energy may be stored in the battery until a sufficient amount has been accumulated to power the tracking mechanism re-enabling solar panel reorientation and thus increased electrical energy generation.

Finally, the light received by space-based photovoltaic devices does not correspond to the AM1.5 spectrum, but rather the AMO spectrum, as there is no atmosphere present in space to attenuate certain frequencies of the solar spectrum. (The AMO standard is described in ATSM International document ASTM E490-00a(2014), which is incorporated herein by reference in its entirety.) For the purposes of the present specification, all cell efficiencies should be understood to be measured based on the AMO spectrum modified by the OTF of the optical system containing the cell, unless otherwise specified.

A satellite equipped with a conventional CPV sunlight harvesting system would be incapable of using sunlight outside of its narrow range of acceptance to generate electrical energy. Thus, in a similar situation, such a satellite would likely be incapable of accumulating stored energy in its battery over time and therefore incapable of re-enabling reorientation of its sunlight acceptance surface (without outside assistance which, in space, is not generally available).

In addition, conventional non-CPV solar panels do not have the aforementioned disadvantage of thermal energy generation as was described above in relation to CPV sunlight harvesting systems. In terrestrial applications, a CPV sunlight harvesting system can ultimately transfer thermal energy generated by the PV cell to the ambient environment (e.g., air, water, etc.) via conduction and/or convention. In a space-related application, generated thermal energy transfer away from a high-efficiency small-size PV cell becomes a difficult critical design characteristic to meet. For example, a satellite has no ambient environment available to it for conductive or convective heat transfer; thermal energy generated by such a PV cell must be dissipated solely via radiative heat transfer (before the PV cell suffers damage from excessively high temperature).

Currently there is no conventional CPV sunlight harvesting system design able to be used in space-related applications. While current conventional non-CPV solar panel systems are adequate for space-related applications, in some applications, at least one additional benefit (e.g. more electricity generated, or the ability to use a less massive and/or lower volume system, etc.) might be achieved by employing a CPV sunlight harvesting system.

### SUMMARY

It is therefore an object of the present technology to ameliorate at least one of the inconveniences present in a prior art device for harvesting sunlight, and to provide an improved such device (as least as compared with some prior art devices), that may be used particularly, although not exclusively, in a space-related application.

It is a further object of the present technology to provide a CPV sunlight harvesting system that may be used particularly, although not exclusively, in a space-related application.

Thus, in one aspect, the present technology provides a device for harvesting sunlight including a frame, and a plurality of sunlight harvesting units connected to and supported by the frame. Each one of the plurality of sunlight harvesting units includes a first reflector having a first reflective surface having a first axial plane and shaped and positioned to focus light parallel to the first axial plane impinging on the first reflective surface. Each one of the plurality of sunlight harvesting units also includes a second reflector having a second reflective surface having a second axial plane and shaped and positioned to focus light parallel to the second axial plane impinging on the second reflective surface.

Further, in each one of the plurality of sunlight harvesting units a first light collection unit is positioned proximate the second reflector and oriented to receive light having been reflected off the first reflective surface. The first light collection unit has a first lower-efficiency photovoltaic cell and a first higher-efficiency photovoltaic cell in thermal communication with the first lower-efficiency photovoltaic cell to allow the first lower-efficiency photovoltaic cell to act as a heat sink for the first higher-efficiency photovoltaic cell. The first higher-efficiency photovoltaic cell has an efficiency at least 1.1 times an efficiency of the first lower-efficiency photovoltaic cell, taking into account optical transfer functions of the device. The first lower-efficiency photovoltaic cell and the first higher-efficiency photovoltaic cell are positioned and arranged such that at least a portion of sunlight parallel to the first axial plane impinging on the first reflective surface and reflected thereby is focused on the first higher-efficiency photovoltaic cell, and at least a portion of sunlight non-parallel to the first axial plane impinging on the first reflective surface and reflected thereby is collected by the first lower-efficiency photovoltaic cell.

Still further, in each one of the plurality of sunlight harvesting units a second light collection unit is positioned proximate the first reflector and oriented to receive light having been reflected off the second reflective surface. The second light collection unit has a second lower-efficiency photovoltaic cell and a second higher-efficiency photovoltaic cell in thermal communication with the second lower-efficiency photovoltaic cell to allow the second lower-efficiency photovoltaic cell to act as a heat sink for the second higher-efficiency photovoltaic cell. The second higher-efficiency photovoltaic cell has an efficiency at least 1.1 times an efficiency of the second lower-efficiency photovoltaic cell, taking into account the optical transfer functions of the device. The second lower-efficiency photovoltaic cell and the second higher-efficiency photovoltaic cell are positioned and arranged such that at least a portion of sunlight parallel to the second axial plane impinging on the second reflective surface and reflected thereby is focused on the second higher-efficiency photovoltaic cell, and at least a portion of sunlight non-parallel to the second axial plane impinging on the second reflective surface and reflected thereby is collected by the second lower-efficiency photovoltaic cell.

Thus, the present technology aims to provide a sunlight harvesting system/device design that is able to be engineered for use in at least one space-related application. In such a system, as was described above, a lower-efficiency photovoltaic cell is able to act as a heat sink for a higher-efficiency photovoltaic cell. This allows for an amount of thermal energy generated by the higher-efficiency photovoltaic cell to be transferred away from that cell to the lower-efficiency photovoltaic cell, which will in turn radiate that thermal energy. Thus, the risk of the high-efficiency cell overheating can be reduced. Further, at least in some cases, when sunlight impinges on a reflective surface at an angle outside of the acceptance angle of the CPV system (and thus is not reflected towards and collected by a higher-efficiency photovoltaic cell), at least some of that sunlight is reflected towards, and collected by, a lower-efficiency photovoltaic cell. Thus, the risk of the sunlight harvesting system not being able to generate any power is reduced. Additionally, by using a mixture of higher-efficiency photovoltaic cells and lower-efficiency photovoltaic cells, there is an increase in the overall energy produced by the panel (compared to using only the lower-efficiency photovoltaic cells), while reducing overall system costs (compared to using only the higher-efficiency photovoltaic cells).

In some embodiments, the frame includes a panel extending below the plurality of sunlight harvesting units and a plurality of support members are connected to and extend away from a face of the panel. For a given one of the plurality of sunlight harvesting units, the first light collection unit is connected to a first support member of the plurality of support members, and the second light collection unit is connected to a second support member of the plurality of support members. In some embodiments, the panel could be rigid, reducing some mounting requirements for the system. In some embodiments, the panel is flat. In some other embodiments, the panel is not flat, for example, to allow mounting of the device on a surface which is not flat, for example on a rounded surfaces.

In some embodiments, the plurality of support members are at a right angle to the face of the panel.

In some embodiments, the plurality of support members are at a non-right angle to the face of the panel. Support members at non-right angles to the face of the panel may permit the device to be used on a surface which is slanted at an angle to the sun, for example on the side of a high-atmosphere blimp

In some embodiments, in each one of the plurality of sunlight harvesting units, the first reflective surface is an off-axis parabolic section in cross-section having an axis (which would be the axis of symmetry of the parabola defining that parabolic section). This axis is parallel to the first axial plane. The second reflective surface is an off-axis parabolic section in cross-section having an axis (which would be the axis of symmetry of the parabola defining that parabolic section). This axis is parallel to the second axial plane.

In some embodiments, in each one of the plurality of sunlight harvesting units, the first axial plane and the second axial plane are parallel.

In some embodiments, in each one of the plurality of sunlight harvesting units, the first axial plane and the second axial plane are co-planar.

In some embodiments, in each one of the plurality of sunlight harvesting units, the first reflector and the second reflector are integral and the first reflective surface and the second reflective surface form a single smooth reflecting surface.

In some embodiments, each of the plurality of sunlight harvesting units are symmetric about the first and second axial planes.

In some embodiments, in each one of the plurality of sunlight harvesting units, at least one of, the first lower-efficiency photovoltaic cell is positioned adjacent to the first higher-efficiency photovoltaic cell; and the second lower-efficiency photovoltaic cell is positioned adjacent to the second higher-efficiency photovoltaic cell.

In some embodiments, in each one of the plurality of sunlight harvesting units, at least one of, the first higher-efficiency photovoltaic cell is disposed on an attachment surface of the first lower-efficiency photovoltaic cell; and the second higher-efficiency photovoltaic cell is disposed on an attachment surface of the second lower-efficiency photovoltaic cell. In some embodiments, both of the foregoing conditions occur. In either of such embodiments, the lower-efficiency cell could be used as a substrate for electrical connections with high-efficiency cell.

In some embodiments, in each one of the plurality of sunlight harvesting units, at least one of, the first lower-efficiency photovoltaic cell is integral with the first higher-efficiency photovoltaic cell; and the second lower-efficiency photovoltaic cell is integral with the second higher-efficiency photovoltaic cell. In some embodiments, both of the foregoing conditions occur.

In some embodiments, in each one of the plurality of sunlight harvesting units, at least one of the following occurs: (1) The first lower-efficiency photovoltaic cell has a total radiating surface area that is sufficiently sized, arranged and oriented to dissipate sufficient thermal energy to maintain a temperature of the first higher-efficiency photovoltaic cell below a maximum operating temperature of the first higher-efficiency photovoltaic cell during operation of the sunlight harvesting unit. (2) The second lower-efficiency photovoltaic cell has a total radiating surface area that is sufficiently sized, arranged and oriented to dissipate sufficient thermal energy to maintain a temperature of the second higher-efficiency photovoltaic cell below a maximum operating temperature of the second higher-efficiency photovoltaic cell during operation of the sunlight harvesting unit. In some embodiments, both of the foregoing conditions occur. Thus, the risk of breakdown of the photovoltaic cells and permanent damage to the sunlight harvesting system, due to exceeding the maximum operating temperature, is reduced.

In some of the foregoing embodiments, in each one of the plurality of sunlight harvesting units, at least one of the following also occurs: (3) The total radiating surface area of the first lower-efficiency photovoltaic cell is sufficiently sized, arranged and oriented to dissipate sufficient thermal energy to maintain a temperature of the first lower-efficiency photovoltaic cell below a maximum operating temperature of the first lower-efficiency photovoltaic cell during operation of the sunlight harvesting unit. (4) The total radiating surface area of the second lower-efficiency photovoltaic cell is sufficiently sized, arranged and oriented to dissipate sufficient thermal energy to maintain a temperature of the second lower-efficiency photovoltaic cell below a maximum operating temperature of the second lower-efficiency photovoltaic cell during operation of the sunlight harvesting unit. In some embodiments, both of the foregoing conditions occur.

In some embodiments, in each one of the plurality of sunlight harvesting units, at least one of the following occurs: (1) The total radiating surface area of the first lower-efficiency photovoltaic cell and a total light-receiving surface area of the first lower-efficiency photovoltaic cell are equal. (2) The total radiating surface area of the second lower-efficiency photovoltaic cell and a total light-receiving surface area of the second lower-efficiency photovoltaic cell are equal. In some embodiments, both of the foregoing conditions occur.

In some embodiments, in each one of the plurality of sunlight harvesting units, at least one of the following occurs: (1) The first lower-efficiency photovoltaic cell has a total light-receiving surface area at least 2 times as large as a total light-receiving surface area of the first higher-efficiency photovoltaic cell. (2) The second lower-efficiency photovoltaic cell has a total light-receiving surface area at least 2 times as large as a total light-receiving surface area of the second higher-efficiency photovoltaic cell. In some embodiments, both of the foregoing conditions occur.

In some embodiments, in each one of the plurality of sunlight harvesting units, at least one of the following occurs: (1) A thermal-energy-radiating and light-receiving surface of the first lower-efficiency photovoltaic cell positioned and oriented such that a line normal to the thermal-energy-radiating and light-receiving surface of the first lower-efficiency photovoltaic is perpendicular the first axial plane. (2) A thermal-energy-radiating and light-receiving surface of the second lower-efficiency photovoltaic cell positioned and oriented such that a line normal to the thermal-energy-radiating and light-receiving surface of the second lower-efficiency photovoltaic is perpendicular the second axial plane. In some such embodiments, both of the foregoing conditions occur. Orienting the photovoltaic cells parallel to the axial planes decreases obstruction of incoming sunlight that is parallel to the axial planes. Further, when sunlight is incident on the device at an angle non-parallel to the axial plane, orienting the photovoltaic cells parallel to the axial planes may allow the photovoltaic cells to absorb some additional sunlight, including in some scenarios directly absorbing a portion of the incident sunlight before the sunlight is incident on the reflecting surfaces.

In some embodiments, in each one of the plurality of sunlight harvesting units, at least one of the following occurs: (1) A portion of sunlight entering the first sunlight harvesting unit non-parallel to the first axial plane is collected by at least one of the first lower-efficiency photovoltaic cell and the second lower-efficiency photovoltaic cell without first impinging on either one of the first reflective surface or the second reflective surface. (2) A portion of sunlight entering the second sunlight harvesting unit non-parallel to the second axial plane is collected by at least one of the first lower-efficiency photovoltaic cell and the second lower-efficiency photovoltaic cell without first impinging on either one of the first reflective surface or the second reflective surface. In some such embodiments, both of the foregoing conditions occur. In such embodiments, a portion of sunlight incident on the device is collected without first being reflected by the reflective surfaces.

In some embodiments, in each one of the plurality of sunlight harvesting units, at least one of the first reflective surface and the second reflective surface includes optical micro-structures. Such embodiments allow the device to include generally flat-shaped reflectors, while still providing focusing of the incident sunlight onto the light collection units. Such embodiments can be further useful in devices which include a frame and sunlight harvesting units that are structured and arranged to be laterally collapsible.

In some embodiments, in each one of the plurality of sunlight harvesting units, at least one of the first light collection unit and the second light collection unit is encapsulated in cerium-doped glass. Cerium-doped glasses are more resistant to radiation.

In some embodiments, for two successive sunlight harvesting units of the plurality of sunlight harvesting units, the first light collection unit of a first one of the two successive sunlight harvesting units is positioned back-to-back with the second light collection unit of a second one of the two successive sunlight harvesting units. Back-to-back construction allows, in some embodiments, for successive sunlight harvesting units to be encapsulated together, reducing complexity and cost. In some embodiments similar to a back-to-back construction, a bifacial cell could be used in place of two back-to-back lower-efficiency cells, also reducing complexity and cost.

In some embodiments, for two successive sunlight harvesting units of the plurality of sunlight harvesting units, the first light collection unit of a first one of the two successive sunlight harvesting units is encapsulated with the second light collection unit of a second one of the two successive sunlight harvesting units. In such embodiments with combined encapsulation, there can be an overall reduction of complexity and cost for the device. Further, in some scenarios, one of the successive sunlight harvesting units may radiate heat away from an other unit which is receiving more light than the first one. Thus, the risk that the sunlight harvesting system operates over the maximum operating temperature is reduced.

In some embodiments, at least a portion of the frame and at least some of a plurality of sunlight harvesting units are structured and arranged to be laterally collapsible. Such a construction may assist in rendering a device more amenable to transport into space.

In some embodiments, in each one of the plurality of sunlight harvesting units, at least one of, the first lower-efficiency photovoltaic cell is a first crystalline silicon photovoltaic cell and the first higher-efficiency photovoltaic cell is a first III-V photovoltaic cell; and the second lower-efficiency photovoltaic cell is a second crystalline silicon photovoltaic cell and the second higher-efficiency photovoltaic cell is a second III-V photovoltaic cell.

In some embodiments, in each one of the plurality of sunlight harvesting units, at least one of, the first lower-efficiency photovoltaic cell is a first single junction photovoltaic cell and the first higher-efficiency photovoltaic cell is a first multi-junction photovoltaic cell; and the second lower-efficiency photovoltaic cell is a second single junction photovoltaic cell and the second higher-efficiency photovoltaic cell is a second multi-junction photovoltaic cell.

In some embodiments, typically those related to applications in space, the efficiencies of the first lower-efficiency photovoltaic cell, the first higher-efficiency photovoltaic cell, the second lower-efficiency photovoltaic cell, and the second higher-efficiency photovoltaic cell are each measured using sunlight defined by an AMO spectrum.

In some embodiments, typically those related to applications in Earth's atmosphere, the efficiencies of the first lower-efficiency photovoltaic cell, the first higher-efficiency photovoltaic cell, the second lower-efficiency photovoltaic cell, and the second higher-efficiency photovoltaic cell are each measured using sunlight defined by an AM1.5 direct normal incidence spectrum.

Thus, the present technology also aims to provide a sunlight harvesting system and device design that is able to be engineered for use in at least one earth-bound or lower atmosphere related application. In such a system, as was described above, a lower-efficiency photovoltaic cell is able to act as a heat sink for a higher-efficiency photovoltaic cell. This allows for an amount of thermal energy generated by the higher-efficiency photovoltaic cell to be transferred away from that cell to the lower-efficiency photovoltaic cell, which will in turn radiate that thermal energy. Depending on the design, the lower-efficiency photovoltaic cell may be able to directly transfer thermal energy to the ambient atmosphere via conduction and convention as well. Again, the risk of the high-efficiency cell overheating can be reduced in Earth-atmosphere applications as opposed to space applications, but this may not always be the case.

Embodiments of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of embodiments of the present technology will become apparent from the following description, the accompanying drawings and the appended claims.

### BRIEF DESCRIPTION OF THE DRAWINGS

Embodiments of the present technology will now be described more fully with reference to the accompanying drawings in which:

FIG. 1 is a top, side perspective view of a device for harvesting sunlight according to one non-limiting embodiment of the present technology;

FIG. 2 is a cross-section of the portion of the device of FIG. 1, taken along line 2-2 of FIG. 1;

FIG. 3A is a close-up portion of the cross-section of FIG. 2, taken from portion 3 of FIG. 2, with on-axis incident light being illustrated;

FIG. 3B is the close-up portion of FIG. 3A, with off-axis incident light being illustrated;

FIG. 3C is a graph illustrating an example of power generation by the device of FIG. 1;

FIG. 4 is a close-up of light collection units of the device of FIG. 1, taken along line 4-4 of FIG. 1;

FIGS. 5A-5D are cross-sectional views of non-limiting embodiments of light collection units according to the present technology;

FIG. 6 is a top, side perspective view of a portion of laterally collapsible device for harvesting sunlight according to another non-limiting embodiment of the present technology;

FIG. 7 is a cross-section of the device of FIG. 6, taken along line 7-7 of FIG. 6;

FIGS. 8A-8D are side elevation views of the device of FIG. 6, illustrated at different stages of collapsing the device of FIG. 6;

FIG. 9 is a side elevation view of a portion of a device for harvesting sunlight according to yet another non-limiting embodiment of the present technology; and

FIG. 10 is a close-up portion of the portion of the device of FIG. 9, taken from portion 10 of FIG. 9.

It should be noted that the drawings are not necessarily to scale unless otherwise explicitly specified herein. It should also be noted that the drawings are not engineering plans unless otherwise explicitly specified herein.

### DETAILED DESCRIPTION OF CERTAIN EMBODIMENTS

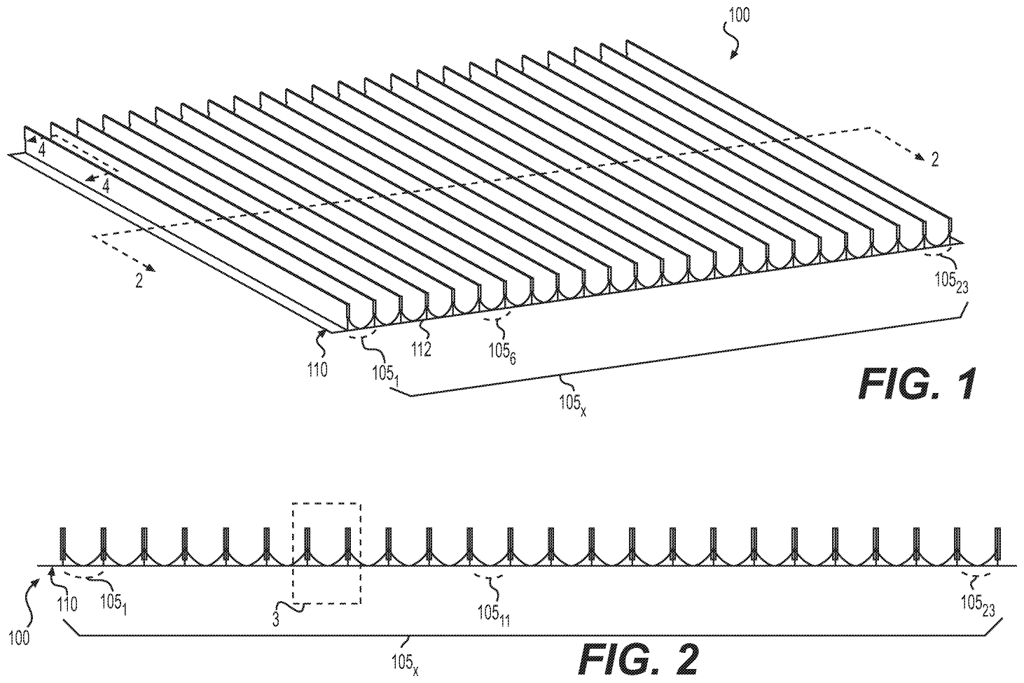

For a better understanding of various features of the present technology, reference is made to the following description which is accompanied by FIGS. 1 to 10.

With reference to FIGS. 1 to 5C, a first non-limiting embodiment of the present technology, device 100 for harvesting sunlight will be described. It is to be expressly understood that the device 100 is merely an embodiment of the present technology. Thus, the description thereof (and of other embodiments) that follows is intended to be only a description of illustrative examples of the present technology. This description is not intended to define the scope or set forth the bounds of the present technology.

In some cases, what are believed to be helpful examples of modifications or alternatives to device 100 (or components thereof) may also be set forth below. This is done merely as an aid to understanding, and, again, not to define the scope or set forth the bounds of the present technology. These modifications are not an exhaustive list, and, as a person skilled in the art would understand, other modifications are likely possible. Further, where this has not been done (i.e. where no examples of modifications have been set forth), it should not be interpreted that no modifications are possible and/or that what is described is the sole manner of implementing or embodying that element of the present technology. As a person skilled in the art would understand, this is likely not the case.

In addition, it is to be understood that the device 100 may provide in certain aspects a simple embodiment of the present technology, and that where such is the case it has been presented in this manner as an aid to understanding. As persons skilled in the art would understand, various embodiments of the present technology may be of a greater complexity than what is described herein.

The device 100 includes a frame 110 for providing structure and strength for the device 100. The frame 110 includes a panel 112, in this case specifically a rigid flat panel 112. It is contemplated that a flexible panel and/or a non-flat panel may be utilized in other embodiments, depending on specifics of any particular embodiment. The rigid panel 112 is made of a thin metallic film, e.g., aluminum, to be lightweight but rigid. It is contemplated that in other embodiments other materials could be used, including but not limited to: titanium, lightweight metal alloys, and polymers such as PMMA and polycarbonate.

The frame 110 includes a plurality of support members 120 connected to and extending away from a face of the rigid panel 112. The support members 120 are also made from thin metal strips in this embodiment. The support members 120 are made from the same material as the panel 112, but it is contemplated that the support members 120 can be made from different materials than the panel 112 in other embodiments. For example, the support members 112 can be made from a variety of materials, including but not limited to: titanium, lightweight metal alloys, glass, and polymers such as PMMA and polycarbonate. For terrestrial applications, the support members 120 can be as thin as 1 millimeter thick, and as thin as 0.6 millimeters for space-based applications. The minimum thickness of the support members 120 depends on the strength necessary to withstand environmental factors (such as wind, rain, atmosphere, gravity, etc.); as such, the members 120 can be thinner for space-based applications. The support members 120 are welded to the rigid panel 112 in this embodiment, although this is not meant to be limiting. Different methods of connecting the support members 120 and the rigid panel 112 can be utilized in other embodiments, including but not limited to: gluing the support members 120 to the panel 112 and the support members 120 being formed integrally with the panel 112. The support members 120, also referred to as blades 120, extend across the width of the panel 112, creating an overall corrugated-like form to the device 100 (see FIG. 1). The blades 120 are oriented at a right angle to the face of the rigid panel 112, but as will be described below, this is not the only possible orientation. In some embodiments, the blades 120 may not be rigid members, but instead could be more flexible and also may be provided with additional structure to orient and support the blades 120.

The device 100 also includes a plurality of sunlight harvesting units 105 connected to and supported by the frame 110. The sunlight harvesting units 105 provide concentration of incident sunlight and subsequent collection of the concentrated light; specifics of their operation will be discussed in more detail below. As described below, in the present embodiment, all of the sunlight harvesting units 105 are identical to one another and only one will be described. In some other embodiments, however, all the sunlight harvesting units 105 may not be identical and one or more units 105 may differ from the remaining sunlight harvesting units 105.

Each sunlight harvesting unit 105ₓ is supported by and between two of the support members 120. (‘x’ being a variable representing a numerical reference to a particular sunlight harvesting unit.) As is the case with the support members 120, each sunlight harvesting unit 105ₓ also extends across the width of the device 100. In the illustrated embodiment, there are 23 sunlight harvesting units 105ₓ (105₁ to 105₂₃) concatenated together along the length of the device 100, but it is contemplated that there could more or fewer units 105ₓ, depending on the specific embodiment. A number of factors lead to the determination of the exact number of sunlight harvesting units 105ₓ, including but not limited to: desired output voltage, desired output power, sizing constraints, and desired application for the device 100.

Each sunlight harvesting unit 105ₓ includes two light collection units 200aₓ, 200bₓ for absorbing light incident on the device 100 and converting that light into energy. Each sunlight harvesting unit 105ₓ also includes two reflectors 150aₓ and 150bₓ for reflecting light impinging thereon toward the light collection units 200aₓ, 200bₓ (respectively). Each light collection unit 200aₓ, 200b is positioned proximate to one reflector 150bₓ, 150aₓ (respectively) and oriented to receive light having been reflected off a reflective surface 152aₓ, 152bₓ of the other reflector 150aₓ, 150bₓ. The reflectors 150aₓ, 150bₓ will be described below in more detail. Electrical circuitry (not shown for simplicity) connects the cells 210aₓ & 220aₓ together and 210bₓ & 220bₓ together and routes the harvested power to an output power bar (not shown). In some embodiments, each light collection unit 200y_{z} will have 4 electrical leads, positive and negative leads for each of the cells 210y_{z}, 220y_{z}. The light collection units 200y_{z} of the device 100 will then be connected in series and/or parallel, to produce 4 overall device electrical leads, positive and negative leads for each the series of the higher-efficiency cells 220y_{z} and the lower-efficiency cells 210y_{z}. In such an embodiment, these four device leads will be combined in an electrical combination box (not shown) to produce a positive electrical lead and a negative electrical lead for the user. (‘y’ being one of ‘a’ or ‘b’ in this embodiment; ‘z’ being a variable representing a numerical reference to a particular sunlight harvesting unit.)

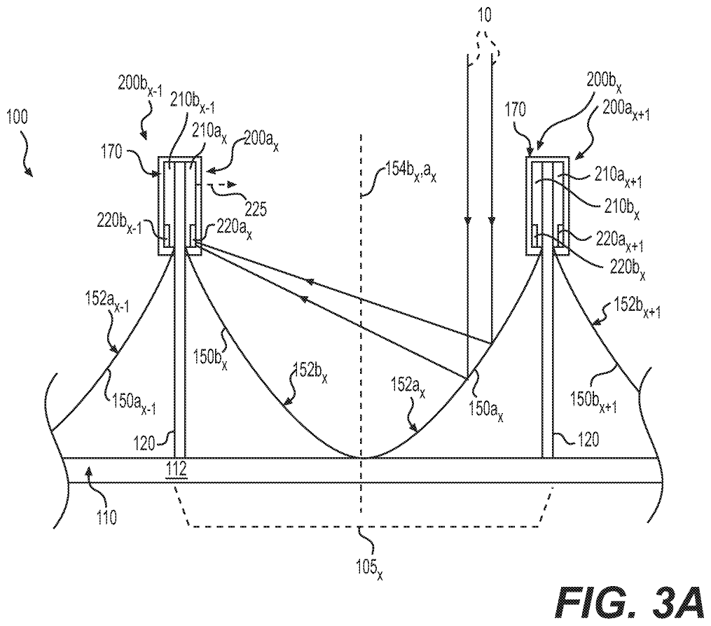

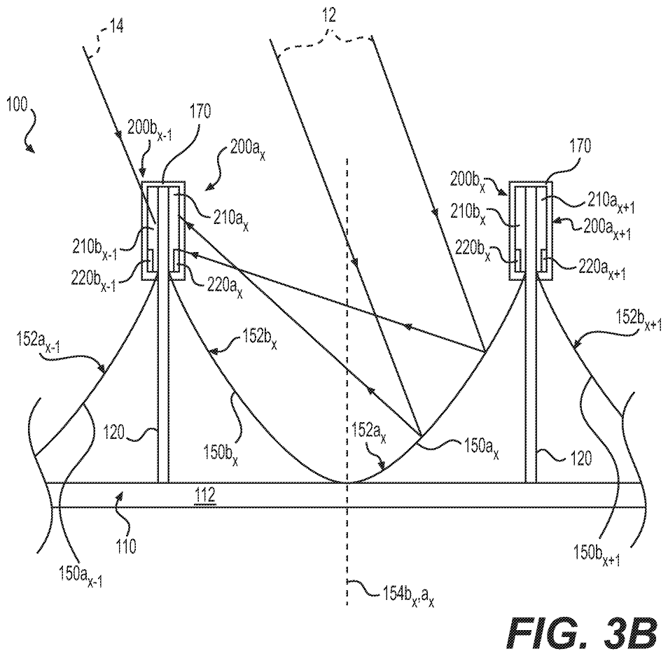

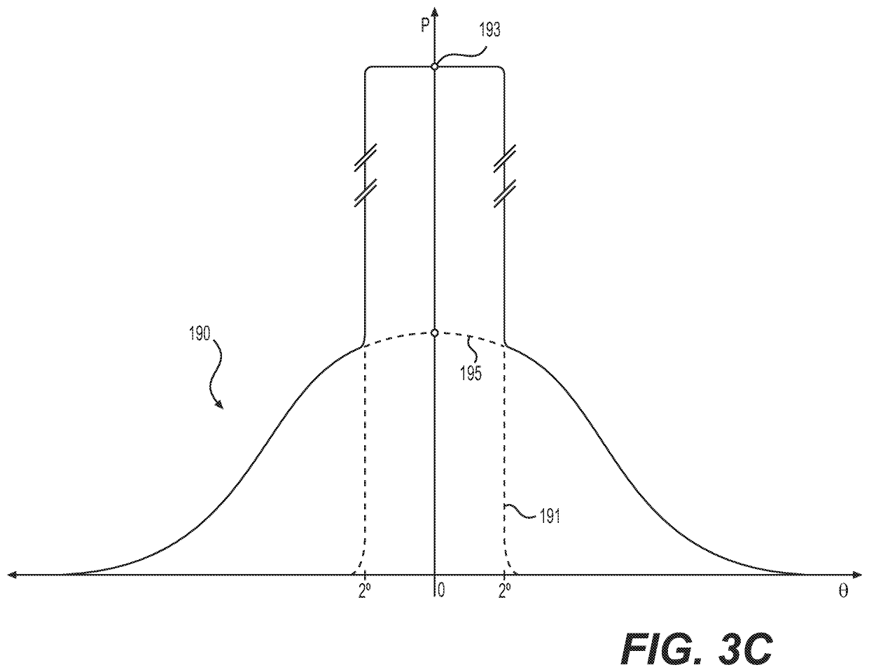

Greater detail of the light collection units 200aₓ, 200bₓ can be seen in FIGS. 3A to 5D. Each light collection unit 200aₓ, 200bₓ includes at least two photovoltaic cells in thermal communication—a lower-efficiency photovoltaic cell 210aₓ, 210bₓ (respectively) and a higher-efficiency photovoltaic cell 220aₓ, 220bₓ (respectively). As will be described below, the lower-efficiency photovoltaic cell 210aₓ, 210bₓ acts at least in part as a heat sink for the higher-efficiency photovoltaic cell 220aₓ, 220bₓ (respectively). Although the present technology does not require any particular specific difference in the power conversion efficiency between the higher-efficiency photovoltaic cell and the lower-efficiency photovoltaic cell, the higher-efficiency photovoltaic cell 220 must have a power conversion efficiency which is at least 1.1 times the power conversion efficiency of the lower-efficiency cell 210, taking into account optical transfer functions of the device and with respect to the appropriate (AMO or AM 1.5) spectrum (depending on the intended application of the device 100)—as is discussed below.

The power conversion efficiency, as is generally known, is the energy produced by a sunlight harvesting device, divided by the energy received. For purposes of the present application, the efficiency necessary at the cells 210y_{z}, 220y_{z} is calculated based on the energy received by the cells 210y_{z}, 220y_{z} being the sunlight spectrum incident on the device 100 (e.g., rays 10), factoring in the optical transfer function (OTF) of the device 100. As one possible application of the sunlight harvesting device 100 is as a space-based sunlight harvester, the sunlight spectrum used to calculate the incident energy, and thus the efficiency ratio between the cells 210y_{z}, 220y_{z}, is the AMO spectrum in such embodiments. In some embodiments, the sunlight harvesting device 100 may be destined for Earth-based applications. In such embodiments, the AM1.5 spectrum would be employed to determine the relevant efficiencies of the lower-efficiency cells 210y_{z} and the higher-efficiency cells 220y_{z}, although the higher-efficiency photovoltaic cell 220y_{z} would still have to have a power conversion efficiency which is at least 1.1 times the power conversion efficiency of the lower-efficiency cell 210y_{z}.

In the present embodiment, the lower-efficiency photovoltaic cell 210y_{z} is a single junction, crystalline Silicon photovoltaic cell 210 (hereinafter “Silicon cell” 210y_{z}), but this is not required to be the case in all embodiments. It is contemplated that different types of photovoltaic cells could be used in different embodiments. For example, in some embodiments, a single junction, amorphous, thin-film silicon cell could be used as the lower-efficiency photovoltaic cell 210y_{z}. The higher-efficiency photovoltaic cell 220y_{z} of the present embodiment is a thin-film, III-V concentrated photovoltaic cell (hereinafter “III-V cell” 220), but this too is not required to be the case in all embodiments. In some other embodiments, the higher-efficiency cell could be made from materials including, but not limited to: GaAs, InGaAs, and InP. It is contemplated that the higher-efficiency photovoltaic cell 220 could be a different multi-junction photovoltaic cell or a different kind of thin-film photovoltaic cell in some embodiments. It is also contemplated that other types of photovoltaic cells could be used, depending on the embodiment. For example, a single junction, III-V cell could be used as the higher-efficiency photovoltaic cell. In some embodiments, both the lower-efficiency photovoltaic cell 210 and the higher-efficiency photovoltaic cell 220y_{z} could be made from crystalline Silicon. The relative functions of the two photovoltaic cells 210y_{z}, 220y_{z} will be described in more detail below.

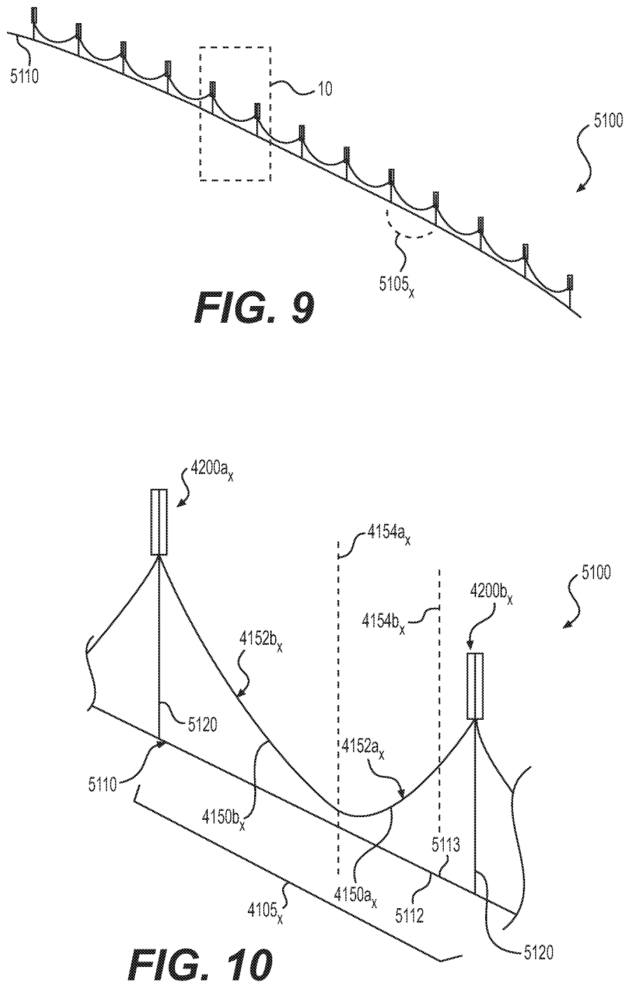

As can be seen in FIGS. 3A-B, the sunlight harvesting units 105ₓ are symmetric about axial planes 154bₓaₓ (described in more detail below). In this embodiment, the units 105ₓ are structurally symmetric, optically symmetric, as well as materially symmetric where the materials used on either side of the axial planes 154bₓaₓ are identical. It is contemplated that the sunlight harvesting units 105ₓ could be none or one or more of structurally symmetric, optically symmetric, and materially symmetric, depending on the particular embodiment. In some embodiments, the sunlight harvesting units 105ₓ may be asymmetric about the axial planes 154bₓaₓ; such an embodiment will be described later with respect to FIGS. 9 and 10.

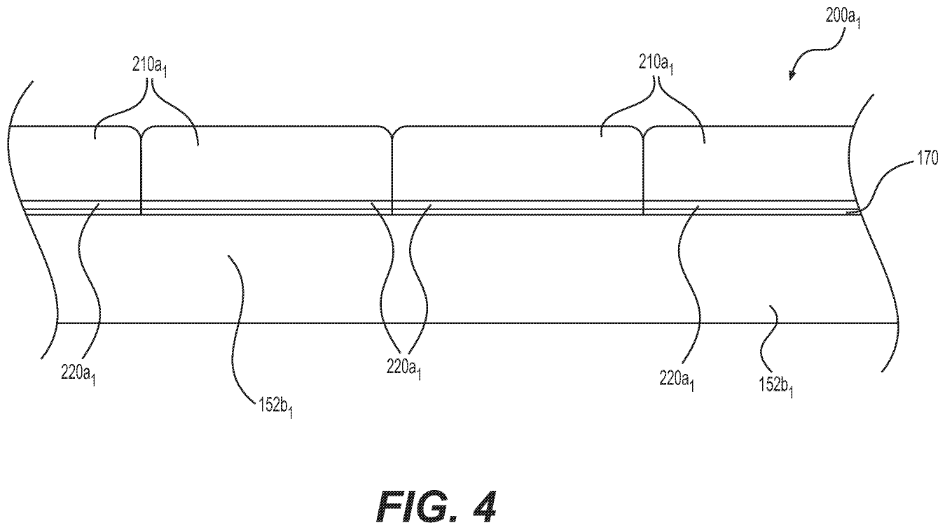

As can be seen from FIG. 4, each light collection unit 200aₓ (with 200a₁ being shown in the FIG.) is generally composed of many photovoltaic cells 210aₓ, 220aₓ (with 210a₁, 210a₂ being shown in the FIG.) connected across the width of a given support member 120 (not shown in the FIG.). Depending on the width of the device 100, more or fewer cells 210aₓ, 220aₓ are necessary to span the total width of the device. For embodiments of the device 100 with a small width, only one of each cell 210aₓ, 220aₓ may be required. Generally, the lower-efficiency cells 210aₓ across the width of the given support member 120 will be connected together, and the higher-efficiency cells 220aₓ across the width of the support member 120 will like-wise be connected together. The lower-efficiency cells 210aₓ could be electrically connected for example through a trace printed on the lower-efficiency cells 210aₓ, a trace on some substrate positioned lower on the a given blade 120, or wires bonded between the cells 210aₓ and/or the cells 220aₓ.

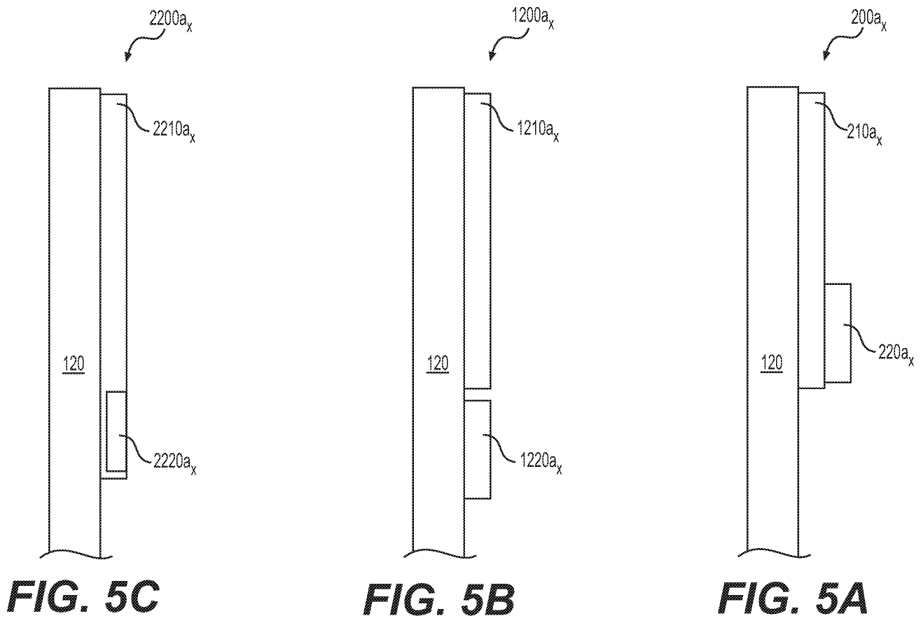

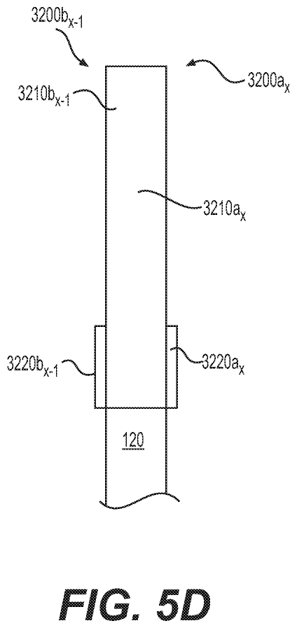

As the sunlight harvesting units 105x are concatenated together along the length of the device, for two successive sunlight harvesting units 105x, 105x+1 of the device 100, one light collection unit 200bₓ of a given sunlight harvesting unit 105x is positioned back-to-back with one of the light collection units 200aₓ₊₁ of a successive sunlight harvesting unit 105x+1. See, for example, FIGS. 3A and 3B. In some embodiments, the Silicon cell 210bₓ, 210aₓ₋₁ can be a bifacial Silicon cell 210y and serve as the lower-efficiency photovoltaic cell 210bₓ, 210aₓ₊₁ of two adjacent (back to back) light collection units 200x, 200ₓ₊₁ (see FIG. 5D).

As is further illustrated in FIG. 3A, the light collection units 200 (e.g., 200bₓ, 200aₓ₊₁) are encapsulated in cerium-doped glass 170 to protect the cells 210, 220 (e.g., 210bₓ, 210aₓ₊₁ 220bₓ, 220aₓ₊₁) from radiation. The cerium-doped glass 170 is laminated over the cells 210, 220 using standard techniques which need not be discussed herein. For two successive sunlight harvesting units 105x, 105ₓ₊₁, the light collection unit 200 (e.g., 200bₓ) of one unit 105 (e.g., 105ₓ) is encapsulated together with the adjacent light collection unit 200 (e.g., 200aₓ₊₁) of a successive sunlight harvesting unit 105 (e.g., 105ₓ₊₁). The cerium-doped glass encapsulation is especially important for space or high-altitudes applications where the device 100 would not be shielded from space radiation by the atmosphere. In embodiments where it is not necessary or desired to shield the cells 210, 220 from radiation, the cerium-doped glass 170 may be omitted.

Different relative arrangements between the photovoltaic cells 210y_{z}, 220y_{z} are possible, some examples of which are illustrated in FIGS. 5A to 5D. It should be noted that the aspect ratios between the cells 210y_{z}, 220y_{z} and the support member 120 are not to scale, and have been exaggerated for ease of illustration. Thermally conducting connections have not been illustrated for clarity, but will be present in all embodiments (as will be discussed below). In the present embodiment and as described herein, the two light collection units 200y_{z} of a given sunlight harvesting unit 105x are identical, but it is contemplated that this may not always be the case. In some embodiments, the two light collection units 200yₓ of a given sunlight harvesting unit 105x could differ from each other, for instance when the light collection units 200yₓ, are oriented at an angle to the frame 110 (e.g. 5110, such as is illustrated in FIG. 9 (described in more detail below)).

The light collection unit 200aₓ of the device 100 is illustrated in FIG. 5A, with the higher-efficiency photovoltaic cell 220aₓ disposed on an attachment surface of the lower-efficiency photovoltaic cell 210aₓ. The two cells 210aₓ, 220aₓ are connected through an electrical and thermal contact sandwiched between the two cells 210aₓ, 220aₓ on the Silicon cell 210aₓ surface (although other methods of connecting the cells 210aₓ, 220aₓ are contemplated for other embodiments).

Another embodiment of a light collection unit 1210aₓ is illustrated in FIG. 5B, where the two photovoltaic cells 1210aₓ, 1220aₓ are both in contact with the support member 120 and are disposed adjacent to one another. In such an embodiment, the two cells 1210aₓ, 1220aₓ would both be connected to an electrical and thermally conducting circuit wedged between the cells 1210aₓ, 1220aₓ and the support member 120. It is contemplated that other methods could be implemented for connecting the cells together in other embodiments, so long as the cells are in thermal communication.

Another embodiment of a light collection unit 2200 is illustrated in FIG. 5C, where the two photovoltaic cells 2210aₓ, 2220aₓ are integral. This could be accomplished, for example, by doping and material deposition of a multi-junction cell 2220aₓ into the Silicon cell 2210aₓ. In such an embodiment, the two cells 2210aₓ, 2220aₓ would be necessarily in thermal communication, and no further steps would be necessary to properly join the cells 2210aₓ, 2220aₓ to each other. It is also contemplated that the multi-junction cell 2220aₓ could be secured directly in a hole etched into the Silicon cell 2210aₓ; the cells 2210aₓ, 2220aₓ would again be directly in thermal contact as in the light collection unit 2200.

Yet another embodiment of two light collection units 3200bₓ₋₁, 3200aₓ is illustrated in FIG. 5D, where the Silicon cell (alternatively referenced as) 3210bₓ₋₁, 3210aₓ is a bifacial Silicon cell that serves as the lower-efficiency photovoltaic cell 3210bₓ₋₁, 3210aₓ for both of two adjacent light collection units 3200bₓ₋₁, 3200aₓ, with the III-V cells 3210bₓ₋₁, 3210aₓ attached to the opposing surfaces of the bifacial Silicon cell 3210bₓ₋₁, 3210aₓ. The cells 3210bₓ₋₁, 3210aₓ 3220bₓ₋₁, 3220aₓ are connected through a thermal contact sandwiched between the cells 3210bₓ₋₁, 3210aₓ, 3220bₓ₋₁, 3220aₓ on the Silicon cell 3210bₓ₋₁, 3210aₓ, surface (although other methods of connecting the cells 3210bₓ₋₁, 3210aₓ, 3220bₓ₋₁, 3220aₓ are contemplated).

Each sunlight harvesting unit 105ₓ includes two reflectors 150aₓ, 150bₓ for reflecting and concentrating light impinging on the device 100 toward the light collection units 200aₓ, 200bₓ (respectively). Each reflector 150aₓ, 150bₓ includes a reflective surface 152aₓ, 152bₓ, (respectively). The reflectors 150aₓ, 150bₓ and reflective surfaces 152aₓ, 152bₓ are made from Silver-coated Titanium film (Ag—Ti film) in the present embodiment. The Ag—Ti film of various thicknesses may be used, including films with thicknesses less than 0.1 mm. In such embodiments, however, the film could be very flexible and may require additional structure to maintain its shape. Many other materials may be utilized in other embodiments, including but not limited to: Aluminum or other metal sheets, metal forms with a Silver coating, and a polymer form with Silver coating. The reflectors 150aₓ, 150bₓ and reflective surfaces 152aₓ, 152bₓ could also be made from different materials from one another in other embodiments.

Each reflective surface 152aₓ, 152bₓ has an axial plane 154aₓ, 154bₓ (respectively) extending across the width of the device 100. As FIG. 3A is a cross-section along the length of the device 100, and as in this embodiment the planes 154aₓ, 154bₓ as co-planar, the planes 154aₓ, 154bₓ are represented as a single line 154b_{x,} aₓ in FIG. 3A. The axial plane 154aₓ 154bₓ for each reflective surface 152aₓ, 152bₓ (respectively) defines the orientation of incident light for which the reflective surface 152aₓ, 152bₓ is designed to have optimal performance Light impinging on the reflective surface 152aₓ, 152bₓ parallel to the plane 154aₓ, 154bₓ (respectively) is generally referred to herein as “on-axis” light; light impinging on the reflective surface 152aₓ, 152bₓ non-parallel to the plane 154aₓ, 154bₓ (respectively) is referred to as “off-axis” light.

The cells 210aₓ, 20aₓ and 210bₓ, 20bₓ and the reflective surfaces 152aₓ, 152bₓ are positioned and arranged such that at least a portion of sunlight parallel to the axial plane 154aₓ, 154bₓ (respectively) impinging on the reflective surface 152aₓ, 152bₓ (the “on-axis” orientation) and reflected thereby is focused on the higher-efficiency photovoltaic cell 220aₓ, 220bₓ (respectively) disposed opposite the reflective surface 152aₓ, 152bₓ in a given sunlight harvesting unit 105x. For sunlight non-parallel to the axial plane 154aₓ, 154bₓ (the “off-axis” orientation), the cells 210aₓ, 20aₓ and 210bₓ, 20bₓ and the reflective surfaces 152aₓ, 152bₓ are positioned and arranged such that at least a portion of the light impinging on the reflective surface 152aₓ, 152bₓ and reflected thereby is collected by the lower-efficiency photovoltaic cell 210aₓ, 210bₓ (respectively).

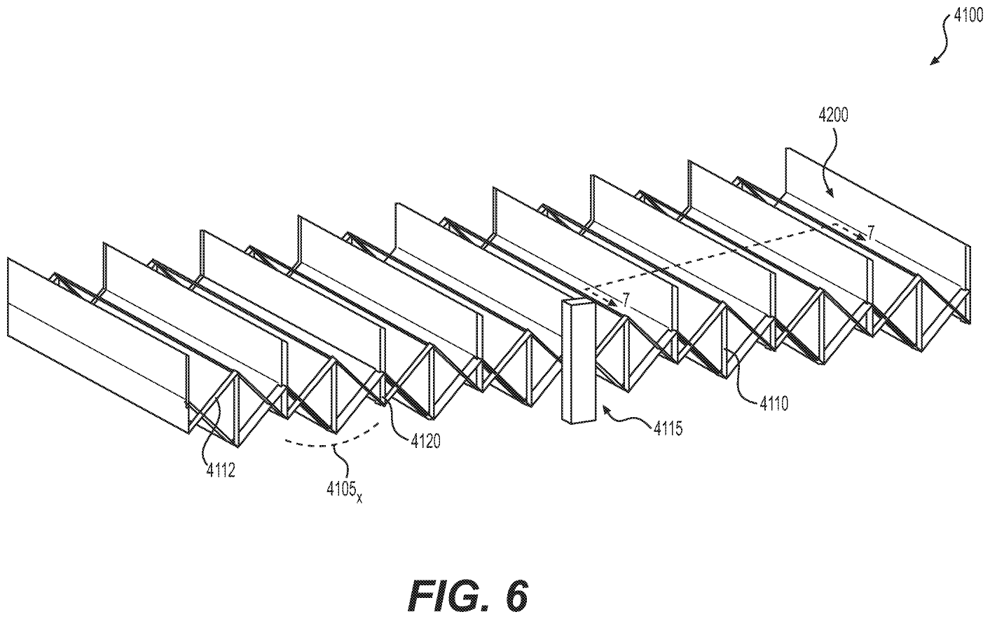

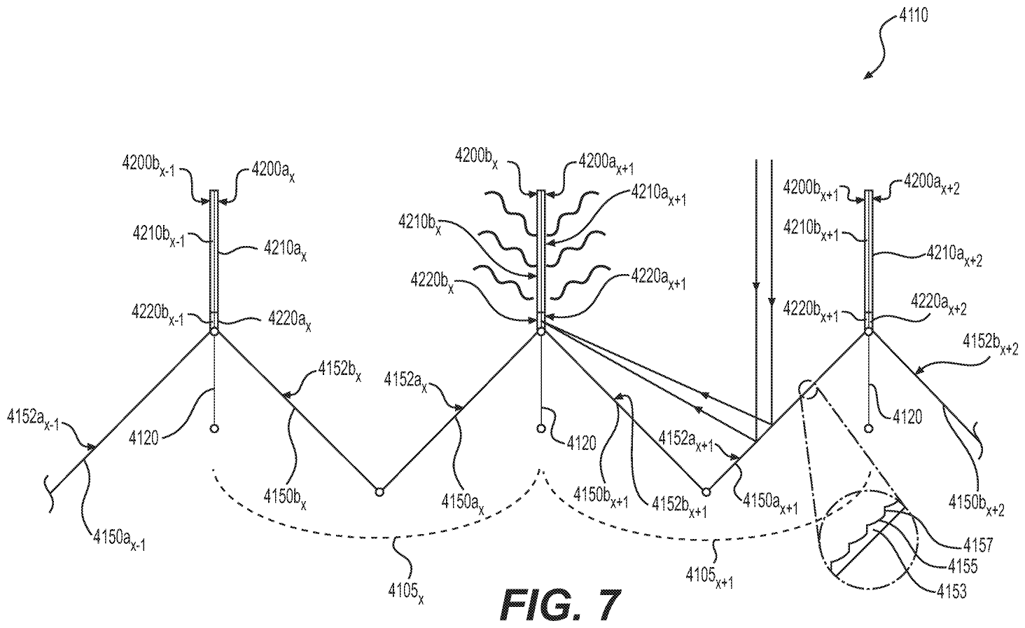

The reflective surfaces 152aₓ, 152bₓ of the present embodiment are off-axis parabolic sections (in cross-section) having an optical axis being the axial plane 154. It is contemplated that in other embodiments, the reflectors 150aₓ, 150bₓ and reflective surfaces 152aₓ, 152bₓ would be formed in a different curved form, including off-axis parabolas with slight variations to improve uniformity of illumination of the light collection units 200aₓ, 200bₓ. (It is also possible to have linear reflectors 4150aₓ 4150bₓ with reflective surfaces 4152aₓ, 4152bₓ that include optical microstructures 4153, as is the case for the embodiment illustrated in FIGS. 6 and 7.)

In this embodiment (i.e. that shown in FIGS. 1-4), the axial planes 154aₓ, 154bₓ of the two reflective surfaces 152aₓ, 152bₓ (respectively) are co-planar, although in other embodiments this is not the case. Further, the two reflectors 150aₓ, 150bₓ of each sunlight harvesting unit 105x are integral and the reflective surfaces 152aₓ, 152bₓ (respectively) form a single smooth reflecting surface; “smooth” here simply refers to the fact that the reflective surfaces 152aₓ, 152bₓ are joined without a discontinuity in the single reflective surface. This is not the case in every embodiment, as the two reflective surfaces 152aₓ, 152bₓ of a given sunlight harvesting unit 105x could be two separate surfaces 152aₓ, 152bₓ, and in some embodiments, may be of different forms (for example, one reflector could form a parabolic section, while the other is of a conic form). In the present embodiment, the sunlight harvesting units 105x of the device 100 are symmetric about the co-planar axial planes, although as can be seen in the embodiment shown in FIGS. 9 and 10, this need not be the case.

As is generally the case with parabolic section reflectors, the reflective surfaces 152aₓ, 152bₓ focus light that impinges thereon to a point for light that is incident at an angle parallel to the plane 154aₓ, 154bₓ (respectively), while light incident at a non-parallel angle is reflected but not focused to a point.

Operation of the device 100 for harvesting sunlight will now be described in more detail with continued reference to FIGS. 3A to 3C. The components will be described below as “right side” (of the line representing planes 154aₓ, 154bₓ) and “left side” (of the same line) components, but this is simply for ease of description and may not be relevant to the actual orientation of the device 100 in use.

In FIG. 3A, the case where the device 100 is orientated such that light rays 10 impinging on the device 100 are incident at an angle parallel to the axial plane 154aₓ is illustrated (on-axis orientation). At least a portion of sunlight parallel to the axial plane 154aₓ impinging on the reflective surface 152aₓ and reflected thereby is focused on the higher-efficiency photovoltaic cell 220aₓ The rays 10 are focused by the right side reflective surface 152aₓ onto the left side light collection unit 200aₓ; although not shown, light incident on the left side reflective surface 152bₓ would be focused onto the right side light collection unit 200bₓ.

The device 100 has up to about a 20× concentration ratio (20 suns) for on-axis light by focusing the light rays 10 onto the higher-efficiency photovoltaic cell 220aₓ in this embodiment. As can be seen in the power to angle graph 190 illustrated in FIG. 3C, the concentrated sunlight captured by the higher-efficiency photovoltaic cell 220aₓ provides a maximum power (labeled 193), but for a very small angular range θ (about 2 degrees around the on-axis alignment). For the present embodiment, maximum power 193 is about 500 Watts, although depending on specific details of a given embodiment the maximum power 193 could be more or less. The curve 191 on the graph 190 represents the power generated by only the higher-efficiency photovoltaic cell 220aₓ. Once the device 100 is oriented such that sunlight is impinging at more than 2 degrees to the axial plane 154aₓ, the power generated by the higher-efficiency photovoltaic cell 220aₓ alone drops to nearly zero.

In FIG. 3B, the case where the device 100 is orientated such that light rays 12 and 14 impinging on the device 100 are incident at an angle non-parallel to the axial plane 154aₓ is illustrated (off-axis sunlight). At least a portion of sunlight non-parallel to the axial plane 154aₓ impinging on the right side reflective surface 152aₓ and reflected thereby is collected by the left side lower-efficiency photovoltaic cell 210aₓ.

To catch the rays 12 reflected from the reflective surface 152aₓ, and to provide sufficient thermal cooling, the lower-efficiency photovoltaic cell 210aₓ, has a total light-receiving surface area at least 2 times as large as a total light-receiving surface area of the higher-efficiency photovoltaic cell 220aₓ. Further, a portion of sunlight, represented by light ray 14, impinging on the device 100 non-parallel to the axial plane 154aₓ is collected by one of the lower-efficiency photovoltaic cells 210bₓ₋₁ without first impinging one of the reflective surfaces 152aₓ₋₁, 152aₓ, 152bₓ, 152bₓ₊₁, shown in the Figure.

A larger lower-efficiency photovoltaic cell 210aₓ will provide more surface area for receiving light from the reflective surfaces 152aₓ, although this will also affect overall device weight, cost, and depth. The ratio between the surface areas of the cells 210aₓ, 20aₓ will also depend on the desired operating temperature of the high efficiency cell 220aₓ, as will be described below.

In the graph 190 of FIG. 3C, the curve 195 represents the power generated by only the lower-efficiency Silicon cell 210aₓ ₓ. As is illustrated therein, the concentrated sunlight captured by the lower-efficiency photovoltaic cell 210aₓ alone provides power over a wide range of angles, although for a lower overall power. For the present embodiment, the maximum power that could be produced by the Silicon cell 210aₓ is about 140 Watts, although depending on specific details of a given embodiment the maximum power could be more or less. The cells 210aₓ, 20aₓ are arranged such that the on-axis light is captured by the III-V cell 220aₓ to produce the most power, but once the device 100 is oriented to receive the sunlight off-axis, the light is reflected onto the lower-efficiency photovoltaic cell 210aₓ such that the device 100 still can generate power.

As can be seen from the above, the combination of the lower and higher-efficiency cells 210aₓ, 20aₓ provides several advantages over using only one of the two cells 210aₓ, 220aₓ. First, the III-V, higher-efficiency cell 220aₓ can be cost intensive, and by concentrating the light onto a smaller area III-V cell 220aₓ, costs can be managed.

This concentration, up to 20 suns in the present embodiment, causes heating of the III-V cell 220, however. The Silicon cell 210aₓ, in thermal communication with the III-V cell 220aₓ, acts as a heat sink for the III-V cell 220aₓ, as Silicon is an efficient radiator. The Silicon cell 210aₓ, has a total radiating surface area that is sufficiently sized, arranged and oriented to dissipate sufficient thermal energy to such that the higher-efficiency photovoltaic cell 220aₓ, remains below a maximum operating temperature during operation of the device 100. Larger Silicon cells 210a will generally provide for more cooling and a lower operating temperatures for the III-V, higher-efficiency photovoltaic cell 220aₓ. If the Silicon cell 210aₓ, is large enough (around X times in area to the III-V cell 220, where X is the concentration ratio), the III-V cell 220aₓ can operate at a temperature equivalent to a cell receiving only 1 sun worth of sunlight. Thus, concentrations of up to 20 suns are possible when oriented to receive sunlight on-axis, while decreasing the risk of loss of efficiency or damage from overheating the III-V cell 220aₓ. Depending on the desired thermal performance, the size of the lower-efficiency cell 210aₓ could be reduced, but the surface area would generally not be reduced to less than 2 times a surface area of the higher-efficiency cell 220aₓ. It is also contemplated that the surface area ratio of lower-efficiency cell 210aₓ to the higher-efficiency cell 220aₓ could be greater than 2, and will generally scale with a desired concentration ratio (as discussed above).

In the present embodiment, the total radiating surface area of the Silicon cell 210aₓ and a total light-receiving surface area of the Silicon cell 210aₓ are equal, as the Silicon cell 210aₓ is simply a blackbody radiator which emits radiation from the same surface into which it absorbs radiation. It is contemplated that this might not always be the case, for example, in some embodiments portions of the Silicon cell 210aₓ may be masked or shaded such that the portions cannot receive light, but radiation is allowed to be emitted from those portions.

In addition to being an effective radiator, the Silicon cell 210aₓ is oriented, with respect to the sunlight impinging on the device 100, perpendicular to the orientation in solar panels as commonly known in the art. As can be seen in at least FIG. 3A, the thermal radiating surface of the lower-efficiency photovoltaic cell 210aₓ (the same as the light receiving surface) is positioned and oriented such that a normal 225 to the thermal radiating surface of the lower-efficiency photovoltaic 210aₓ is perpendicular the axial plane 154aₓ. As such, the direction of emitted radiation from the Silicon cell 210aₓ is not oriented facing toward the sun and the radiation to be emitted is not generally impeded by incoming radiation from the sun. Further, since the Silicon cell 210aₓ is a blackbody radiator, the direction of greatest emission is along the direction of the normal 225 and the angles of greatest radiative emission (and thus providing the most cooling) are thus oriented perpendicular to the incident radiation.

It should be noted that while the thermal-energy-radiating surface is not oriented facing toward the sun, it is positioned and oriented such that some of the thermal-energy radiated will be radiated towards other parts of the device 100 in this embodiment. For example, thermal radiation from one light collection unit 200aₓ of a given sunlight harvesting unit 105x may be partially absorbed by the other light collection unit 200bₓ of the given sunlight harvesting unit 105x. At least in some embodiments, the device 100 is arranged to take possible reabsorption into account, and the Silicon cells 210aₓ, for example, are sized to radiate sufficient thermal energy to cool the high-efficiency photovoltaic cell 220aₓ, as well as to radiate enough thermal energy to compensate for possible reabsorption. The exact percentage of thermal radiation impacting on or being reabsorbed by different parts of the device 100 will depend on the structural, material, and application details of any given embodiment.

As mentioned above, inclusion of the Silicon cell also provides power generation when the device 100 is oriented off-axis. For embodiments where the device 100 is meant to be the main or only source of power for an apparatus (for instance in space or high altitude related application), being able to generate enough power to re-orient the device 100 back to an on-axis orientation could be highly advantageous. Without off-axis performance, an apparatus utilizing the device 100 would need energy storage in order to power re-orientation if the apparatus becomes misaligned with the sun. By improving off-axis performance, energy storage requirements are mitigated.

Another non-limiting embodiment of a device 4100 for harvesting sunlight will now be described with reference to FIGS. 6 to 8D. Features presented with respect to the device 100 will not be reintroduced and retain their same reference numerals.

The device 4100 is a laterally collapsible/foldable device 4100 with a lightweight accordion support frame 4110, also referred to as an accordion module. The frame 4110 is a lightweight truss, made using any strong, lightweight steel. The frame 4110 can be made from different materials depending on the embodiment, including but not limited to: aluminum, PMMA, and polycarbonate. If the device 4100 is to be deployed in a space-based embodiment, the material of the frame 4110 should be space-proven, including for example, titanium.

At least a portion of the frame 4110 and at least some sunlight harvesting units 4105x are structured and arranged to be laterally collapsible. The frame 4110 includes accordion members 4112 connected together via hinges. As is illustrated in FIG. 7, the device 4100 includes similar light collection units 4200 in order to provide similar power generation and thermal properties as the device 100. The light collection units 4200y_{z} are connected to support members 4120, which are also known as thin blades. The frame 4110 includes blockers for preventing the device 4100 from being over extended, although the device 4100 need not have the blockers in every embodiment. In some embodiments, rigidity for the device could be provided externally such that the frame 4100 could be mounted such that it is held open.

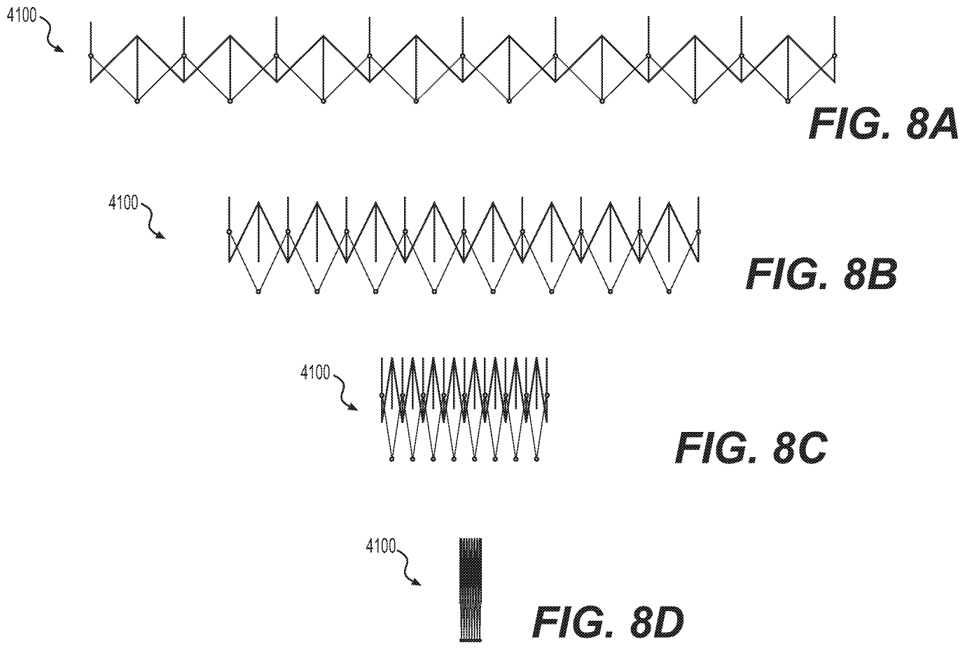

In this manually collapsible/expandable embodiment, the blades 4120 are connected to the accordion members 4112, instead of a rigid panel. The frame 4110 is compressed when the accordion members 4112 pivot at their connecting hinges, such that the blades 4120 are pushed towards one another. FIGS. 8A to 8D schematically illustrate four steps in collapsing the device 4100 from the fully extended, operating position (FIG. 8A) to a fully collapsed and pack position (FIG. 8D). A locking mechanism (not shown) is included to keep the frame 4100 open in the fully extended position during operation, although it could also be held open through tension, for example.

The accordion module 4100 is further collapsible for improved portability, but it should also be noted that the overall depth of the device 4100 will generally be greater than that of the device 100. Portability and collapsibility may also lead to a relaxation of design limitations due to environmental factors, for example the strength of the frame 4110, as the device 4100 can be more readily taken down and protected from harsh environmental factors, such as high winds and hail.

The frame 4110 further includes a pole mount 4115 for installation of the device 4100 on a pole, or onto a wall. Within the mount 4115 (not shown), the device 4110 includes a single-axis tracker for alignment with the incident sunlight, a power controller, a battery, and a power bar. It is contemplated that the movement and power related components would be provided separately from the mount 4115.

In order to provide the device 4110 that is collapsible for improved portability, the reflectors 4150y_{z} generally need to be flat, or nearly flat, to minimize a collapsed volume of the device 4100. The flat reflectors 4150y_{z} are especially useful for flat packing the device 300, but in some embodiments it is contemplated that the reflectors 4150y_{z} may not be flat and could have different forms depending specific details of the embodiment. The flat reflectors 4150y_{z} are generally 75 to 150 micrometers thick, although this may vary depending on the particular embodiment. The flat reflectors 4150y_{z} are molded, mirror coated PMMA structures, but different materials can be used, including but not limited to polycarbonate.

The flat reflectors 4150y_{z} of the device 4100 include a reflective surface 4152y_{z} (respectively) which includes microstructures 4153 to produce a focusing effect in order to focus on-axis light onto the higher-efficiency photovoltaic cell 4220y_{z} (as described above with respect to device 100). The microstructures 4153 are molded into the flat reflectors 4150y_{z} and are subsequently mirror-coated (although alternative techniques such as embossing are contemplated). As is illustrated in the inset of FIG. 7, in this embodiment the microstructures 4153 include small parabolic sections 4155 interconnected by vertical segments 4157. The number of parabolic sections 4155 and the size of the vertical segments 4157 could depend on the size of the reflector 4150y_{z}, the angle of orientation of the reflector 4150y_{z}, and/or the number of parabolic sections of the reflective surface 4152y_{z}. It is also contemplated that optical reflector forms other than parabolic could be employed in other embodiments. The microstructures 4153 are not limited to the collapsible device 4100, and may be used in cooperation of the device 100 described above in other embodiments.

Although in this embodiment, the device 4100 is manually expandable and collapsible, mechanized embodiments are also possible.

Another non-limiting embodiment of a device 5100 for harvesting sunlight will now be described with reference to FIGS. 9 and 10. Features presented with respect to the device 100 will not be reintroduced and retain their same reference numerals.

The device 5100 is designed for an “on-axis” orientation which is not perpendicular to the frame orientation, for example for placement on a surface whose normal is not oriented toward the impinging sunlight.

The device 5100 includes a frame 5110, which includes a panel 5112 and a plurality of support members 5120. In this embodiment, the panel 5112 is a rigid panel, but it is contemplated that structure necessary to hold the device could be provided when mounting the device 5100, and need not necessarily come from the panel 5112 being a rigid panel. Further, the panel 5112 is slightly curved, rather than flat like the panel 112, such that it can be mounted on a curved support surface. It is contemplated that the panel 5112 could be more or less curved than illustrated in FIG. 9. It is also contemplated that in some embodiments the panel 5112 could be flat.

In contrast to the frame 5110 of the device 100, the support members 5120 are at a non-right angle to the face 5113 of the rigid panel 5110. The device 5100 with support members 5120 at non-right angles to the face 5113 is intended to be used in scenarios where the face is not oriented with its normal pointing at the sun. A variety of different non-right angles could be employed in different embodiments; the support members 5120 will generally be between +/−45 degrees of a right-angle orientation to the face 5113 of the rigid panel 5110.

The device 5100 is composed of a plurality of sunlight harvesting units 5105x made up of two light collection units 5200aₓ, 5200bₓ and two reflectors 5150aₓ, 5150bₓ having a reflective surface 5152aₓ, 5152bₓ each. The support members 5120 support the light collection units 5200aₓ, 5200bₓ as before, and the two reflectors 5152aₓ, 5152bₓ are disposed between and supported by two support members 5120.

In this embodiment, axial planes 5154aₓ, 5154bₓ of the two reflective surfaces 5152aₓ, 5152bₓ (respectively) are parallel (although not co-planar). It is contemplated that in other non-limiting embodiments axial planes 5154aₓ, 5154bₓ of the two reflective surfaces 5152aₓ, 5152bₓ could be non-parallel. Further, the two reflectors 5150aₓ, 5150bₓ of each sunlight harvesting unit 5105x are integral and the reflective surfaces 5152aₓ, 5152bₓ form a single smooth reflecting surface.

Although embodiments have been described above with reference to the accompanying drawings, those of skill in the art will appreciate that variations and modifications may be made without departing from the scope thereof as defined by the appended claims.

Modifications and improvements to the above-described embodiments of the present technology may become apparent to those skilled in the art. The foregoing description is intended to be exemplary rather than limiting. The scope of the present technology is therefore intended to be limited solely by the scope of the appended claims.

1. A device for harvesting sunlight comprising:
a frame; and
a plurality of sunlight harvesting units connected to and supported by the frame, each one of the plurality of sunlight harvesting units including:
a first reflector having a first reflective surface having a first axial plane and shaped and positioned to focus light parallel to the first axial plane impinging on the first reflective surface;
a second reflector having a second reflective surface having a second axial plane and shaped and positioned to focus light parallel to the second axial plane impinging on the second reflective surface;
a first light collection unit positioned proximate the second reflector and oriented to receive light having been reflected off the first reflective surface, the first light collection unit having,
a first lower-efficiency photovoltaic cell, and
a first higher-efficiency photovoltaic cell in thermal communication with the first lower-efficiency photovoltaic cell to allow the first lower-efficiency photovoltaic cell to act as a heat sink for the first higher-efficiency photovoltaic cell, the first higher-efficiency photovoltaic cell having an efficiency at least 1.1 times an efficiency of the first lower-efficiency photovoltaic cell, taking into account optical transfer functions of the device,
the first lower-efficiency photovoltaic cell and the first higher-efficiency photovoltaic cell being positioned and arranged such that:
at least a portion of sunlight parallel to the first axial plane impinging on the first reflective surface and reflected thereby is focused on the first higher-efficiency photovoltaic cell, and
at least a portion of sunlight non-parallel to the first axial plane impinging on the first reflective surface and reflected thereby is collected by the first lower-efficiency photovoltaic cell; and
a second light collection unit positioned proximate the first reflector and oriented to receive light having been reflected off the second reflective surface, the second light collection unit having,
a second lower-efficiency photovoltaic cell, and
a second higher-efficiency photovoltaic cell in thermal communication with the second lower-efficiency photovoltaic cell to allow the second lower-efficiency photovoltaic cell to act as a heat sink for the second higher-efficiency photovoltaic cell, the second higher-efficiency photovoltaic cell having an efficiency at least 1.1 times an efficiency of the second lower-efficiency photovoltaic cell, taking the optical transfer functions of the device into account,
the second lower-efficiency photovoltaic cell and the second higher-efficiency photovoltaic cell being positioned and arranged such that:
at least a portion of sunlight parallel to the second axial plane impinging on the second reflective surface and reflected thereby is focused on the second higher-efficiency photovoltaic cell, and
at least a portion of sunlight non-parallel to the second axial plane impinging on the second reflective surface and reflected thereby is collected by the second lower-efficiency photovoltaic cell.

2. The device of claim 1, wherein
the frame includes:
a panel extending below the plurality of sunlight harvesting units, and
a plurality of support members connected to and extending away from a face of the panel; and
for a given one of the plurality of sunlight harvesting units:
the first light collection unit is connected to a first support member of the plurality of support members; and
the second light collection unit is connected to a second support member of the plurality of support members.

3. (canceled)

4. (canceled)

5. The device of claim 1, wherein, in each one of the plurality of sunlight harvesting units,
the first reflective surface is an off-axis parabolic section in cross-section having an axis, the axis being parallel to the first axial plane; and
the second reflective surface is an off-axis parabolic section in cross-section having an axis, the axis being parallel to the second axial plane.

6. The device of claim 1, wherein, in each one of the plurality of sunlight harvesting units, the first axial plane and the second axial plane are parallel.

7. The device of claim 6, wherein, in each one of the plurality of sunlight harvesting units, the first reflector and the second reflector are integral and the first reflective surface and the second reflective surface form a single smooth reflecting surface.

8. (canceled)

9. The device of claim 1, wherein, in each one of the plurality of sunlight harvesting units, at least one of,
the first lower-efficiency photovoltaic cell is positioned adjacent to the first higher-efficiency photovoltaic cell; and
the second lower-efficiency photovoltaic cell is positioned adjacent to the second higher-efficiency photovoltaic cell.

10. The device of claim 1, wherein, in each one of the plurality of sunlight harvesting units, at least one of,
the first higher-efficiency photovoltaic cell is disposed on an attachment surface of the first lower-efficiency photovoltaic cell; and
the second higher-efficiency photovoltaic cell is disposed on an attachment surface of the second lower-efficiency photovoltaic cell.

11. (canceled)

12. The device of claim 1, wherein, in each one of the plurality of sunlight harvesting units, at least one of,
the first lower-efficiency photovoltaic cell has a total radiating surface area that is sufficiently sized, arranged and oriented to dissipate sufficient thermal energy to maintain a temperature of the first higher-efficiency photovoltaic cell below a maximum operating temperature of the first higher-efficiency photovoltaic cell during operation of the sunlight harvesting unit; and
the second lower-efficiency photovoltaic cell has a total radiating surface area that is sufficiently sized, arranged and oriented to dissipate sufficient thermal energy to maintain a temperature of the second higher-efficiency photovoltaic cell below a maximum operating temperature of the second higher-efficiency photovoltaic cell during operation of the sunlight harvesting unit.

13. (canceled)

14. The device of claim 12, wherein, in each one of the plurality of sunlight harvesting units, at least one of,
the total radiating surface area of the first lower-efficiency photovoltaic cell and a total light-receiving surface area of the first lower-efficiency photovoltaic cell are equal; and
the total radiating surface area of the second lower-efficiency photovoltaic cell and a total light-receiving surface area of the second lower-efficiency photovoltaic cell are equal.

15. The device of claim 1, wherein, in each one of the plurality of sunlight harvesting units, at least one of,
the first lower-efficiency photovoltaic cell has a total light-receiving surface area at least 2 times as large as a total light-receiving surface area of the first higher-efficiency photovoltaic cell; and
the second lower-efficiency photovoltaic cell has a total light-receiving surface area at least 2 times as large as a total light-receiving surface area of the second higher-efficiency photovoltaic cell.

16. The device of claim 1, wherein, in each one of the plurality of sunlight harvesting units, at least one of,
a thermal-energy-radiating and light-receiving surface of the first lower-efficiency photovoltaic cell is positioned and oriented such that a line normal to the thermal-energy-radiating and light-receiving surface of the first lower-efficiency photovoltaic is perpendicular the first axial plane; and
a thermal-energy-radiating and light-receiving surface of the second lower-efficiency photovoltaic cell is positioned and oriented such that a line normal to the thermal-energy-radiating surface of the second lower-efficiency photovoltaic is perpendicular the second axial plane.

17. The device of claim 1, wherein, in each one of the plurality of sunlight harvesting units, at least one of,
a portion of sunlight entering the first light collecting unit non-parallel to the first axial plane is collected by at least one of the first lower-efficiency photovoltaic cell and the second lower-efficiency photovoltaic cell without first impinging on either one of the first reflective surface or the second reflective surface; and
a portion of sunlight entering the second light collecting unit non-parallel to the second axial plane is collected by at least one of the first lower-efficiency photovoltaic cell and the second lower-efficiency photovoltaic cell without first impinging on either one of the first reflective surface or the second reflective surface.

18. The device of claim 1, wherein, in each one of the plurality of sunlight harvesting units, at least one of the first reflective surface and the second reflective surface includes optical micro-structures.

19. (canceled)

20. The device of claim 1, for two successive sunlight harvesting units of the plurality of sunlight harvesting units, the first light collection unit of a first one of the two successive sunlight harvesting units is positioned back-to-back with the second light collection unit of a second one of the two successive sunlight harvesting units.

21. The device of claim 1, for two successive sunlight harvesting units of the plurality of sunlight harvesting units, the first light collection unit of a first one of the two successive sunlight harvesting units is encapsulated with the second light collection unit of a second one of the two successive sunlight harvesting units.

22. The device of claim 1, wherein at least a portion of the frame and at least some of a plurality of sunlight harvesting units are structured and arranged to be laterally collapsible.

23. The device of claim 1, wherein, in each one of the plurality of sunlight harvesting units, at least one of,
the first lower-efficiency photovoltaic cell is a first crystalline silicon photovoltaic cell and the first higher-efficiency photovoltaic cell is a first III-V photovoltaic cell; and
the second lower-efficiency photovoltaic cell is a second crystalline silicon photovoltaic cell and the second higher-efficiency photovoltaic cell is a second III-V photovoltaic cell.

24. The device of claim 1, wherein, in each one of the plurality of sunlight harvesting units, at least one of,
the first lower-efficiency photovoltaic cell is a first single junction photovoltaic cell and the first higher-efficiency photovoltaic cell is a first multi-junction photovoltaic cell; and
the second lower-efficiency photovoltaic cell is a second single junction photovoltaic cell and the second higher-efficiency photovoltaic cell is a second multi-junction photovoltaic cell.

25. The device of claim 1, wherein the efficiencies of the first lower-efficiency photovoltaic cell, the first higher-efficiency photovoltaic cell, the second lower-efficiency photovoltaic cell, and the second higher-efficiency photovoltaic cell are each measured using sunlight defined by an AM1.5 direct normal incidence spectrum.

26. The device of claim 1, wherein the efficiencies of the first lower-efficiency photovoltaic cell, the first higher-efficiency photovoltaic cell, the second lower-efficiency photovoltaic cell, and the second higher-efficiency photovoltaic cell are each measured using sunlight defined by an AMO spectrum.
